(19) United States
(12) Patent Application Publication
(10) Pub. No.: US 2022/0090695 A1
(43) Pub. Date: Mar. 24, 2022

(54) FLUID VALVE CONTROL DEVICE

(71) Applicant: Dongguan Will Power Technology Co.,Ltd., Dongguan City (CN)

(72) Inventor: Jingping TANG, Dongguan City (CN)

(21) Appl. No.: 17/036,586

(22) Filed: Sep. 29, 2020

(30) Foreign Application Priority Data
Sep. 18, 2020 (CN) 202010985232.2

(51) Int. Cl. F16K 31/05; F16K 31/04; H02K 7/116

(52) U.S. Cl. CPC F16K 31/05; H02K 7/116; F16K 31/046; F16K 31/047

(57) ABSTRACT

A fluid valve control device exemplarily uses two laryngeal hoops on the left and right to connect a fluid pipe, uses baffles to connect a fluid valve handle, uses a motor assembly to drive a motor gear, uses the motor gear to drive a limit gear to rotate, and uses the limit gear to drive a turning arm to rotate by a shaft, thereby driving the baffles to control the water valve handle to rotate so as to control the opening size of flowage. Movable slide bars can be adjusted at different angles according to different water pipes and meanwhile movable stands can carry out length telescopic adjustments along the respective movable slide bars, and thus a wide range of application scenarios is achieved. In addition, the fluid valve handle can be stay at any angle between 0 and 90 degrees and therefore it can save water resources.

### TECHNICAL FIELD

The invention relates to the field of fluid valve switch control, and more particularly to a fluid valve control device.

### DESCRIPTION OF RELATED ART

At present, a fluid valve control device e.g., a water valve control device has a fixed point fixedly connected to a water pipe at one end, it is easy to be out of position when opening or closing a water valve. At the same time, when a water valve handle is controlled to be turned/rotated, there are only two states of opening and closing, and a water flow volume cannot be adjusted, resulting in a waste of water.

### SUMMARY

In view of defects and deficiencies of the prior art, that is, in view of the above-mentioned contents, it is necessary to provide a fluid valve control device to solve the deficiencies in the above-mentioned background technology.

In order to achieve the above objective, an embodiment of the invention provides a fluid valve control device including: a housing, a motor assembly, a motor gear, a limit gear, movable slide bars, movable stands, laryngeal hoops, a turning arm and baffles. The motor assembly, the motor gear and the limit gear are placed in the housing. The movable slide bars, the movable stands and the laryngeal hoops together form two sets arranged at two sides of the housing. The movable slide bars are connected with a bottom of the housing, the movable slide bars are formed with sliding grooves respectively, the movable stands respectively are connected with the movable slide bars and slidable along the sliding grooves of the movable slide bars, and the movable stands are connected with the laryngeal hoops respectively. The motor assembly is configured for driving the motor gear to rotate, the motor gear is configured for driving the limit gear to rotate, the limit gear is configured for driving the turning arm to rotate by a shaft, and the baffles are fixedly connected with the turning arm.

In an embodiment of the invention, the fluid valve control device further includes a slide bar positioning buckle. The slide bar positioning buckle is arranged between the housing and one of the movable slide bars. The bottom of the housing is disposed with a plurality of steel ball receiving grooves, the slide bar positioning buckle is disposed with a recess matched with any one of the plurality of steel ball receiving grooves. A steel ball is arranged between the recess and one of the plurality of steel ball receiving grooves. The slide bar positioning buckle is further disposed with a first positioning hole, and the movable slide bar is disposed with a second positioning hole.

In an embodiment of the invention, the baffles include first baffles and second baffles. The first baffles and the second baffles are arranged two sides of the shaft of the limit gear respectively.

In an embodiment of the invention, the first baffle is a L-shaped baffle, and the second baffle is a L-shaped baffle.

In an embodiment of the invention, the limit gear includes a gear teeth part and a cam part.

In an embodiment of the invention, a distance between the cam part and a circle center of the limit gear is greater than a distance between the gear teeth part and the circle center of the limit gear.

In an embodiment of the invention, a central angle of the cam part is 90 degrees to 100 degrees.

In an embodiment of the invention, the fluid valve control device further includes a first limit switch and a second limit switch. The first limit switch and the second limit switch are arranged in the housing, the first limit switch and the second limit switch are arranged two sides of the limit gear respectively. During the limit gear rotates, the cam part of the limit gear is capable of abutting against the first limit switch and the second limit switch, but the gear teeth part of the limit gear is not capable of abutting against the first limit switch and the second limit switch.

In an embodiment of the invention, the fluid valve control device further includes a circuit board. The first limit switch and the second limit switch are connected with the circuit board, a fluid valve (e.g., water valve) is in a maximum fluid discharging state when the cam part of the limit gear abuts against the first limit switch, and the fluid valve is in a closed state when the cam part of the limit gear abuts against the second limit switch.

In an embodiment of the invention, the housing includes an upper casing and a lower casing.

The beneficial effects of the embodiments of the invention are as follows:

The fluid valve control device (e.g., water valve control device) as provided by the invention uses two laryngeal hoops respectively located on the left and right to connect with a fluid pipe (e.g., water pipe), uses the baffles to connect with a fluid valve handle (e.g., water valve handle), uses the motor assembly to drive the motor gear, and uses the motor gear to drive the limit gear to rotate. The limit gear then drives the turning arm to rotate by the shaft and thereby brings the baffles to drive the fluid valve handle to rotate, so as to control the size of fluid flowage. In the invention, fixed points of the fluid valve control device with the fluid pipe are at two ends, which are tightened and fixed by the laryngeal hoops, so that the two fixed points of the fluid valve control device and the shaft are located in a same horizontal plane, the problem that the switch is not in place due to the dislocation and offset of the shaft and the fluid valve handle is solved. The movable slide bars of the invention can be adjusted at different angles according to different fluid pipes, and the movable stands can carry out length telescopic adjustments along the movable slide bars, and therefore a wide range of application scenarios is achieved. The invention may make the fluid valve handle stay at any angle between 0 and 90 degrees and therefore can save water resources. Meanwhile, the invention also adopts a touch sensing method to control the fluid valve, and also has the wireless remote network control function. A remote network connection between a mobile phone APP and the host control system can be established, and then the host control system carries out the remote control. Therefore, the invention is particularly suitable for garden watering, agricultural irrigation and other production and living works as well as the control of gas pipeline switch. The remote control technology can reduce the expenditure cost of production labor and reduce the waste of water resources.

### BRIEF DESCRIPTION OF THE DRAWINGS

In order to more clearly illustrate technical solutions of embodiments of the disclosure, drawings used in the description of the embodiments will be briefly described below. Apparently, the drawings described below are merely some embodiments of the disclosure, and those skilled in the art can obtain other drawings based on these drawings without creative efforts.

FIG. 1 is a first schematic view of a fluid valve control device according to an embodiment of the invention.

FIG. 2 is a schematic front view of the fluid valve control device according to the embodiment of the invention.

FIG. 3 is a second schematic view of the fluid valve control device according to the embodiment of the invention.

FIG. 4 is a third schematic view of the fluid valve control device according to the embodiment of the invention.

FIG. 5 is a schematic view of a motor gear meshed with a limit gear according to the embodiment of the invention.

FIG. 6 is a schematic view of a connection relationship associated with a movable slide bar according to the embodiment of the invention.

FIG. 7 is a first schematic exploded view of the components shown in FIG. 6.

FIG. 8 is a second schematic exploded view of the components shown in FIG. 6.

FIG. 9 is a schematic view of a connection relationship associated with a turning arm according to the embodiment of the invention.

FIG. 10 is a schematic exploded view of the components shown in FIG. 9.

FIG. 11 is a schematic diagram of a first control principle associated with a motor according to an embodiment of the invention.

FIG. 12 is a schematic diagram of a second control principle associated with the motor according to an embodiment of the invention.

FIG. 13 is a schematic diagram of a third control principle associated with the motor according to an embodiment of the invention.

FIG. 14 is a schematic diagram of a fourth control principle associated with the motor according to an embodiment of the invention.

FIG. 15 is a schematic diagram of a fifth control principle associated with the motor according to an embodiment of the invention.

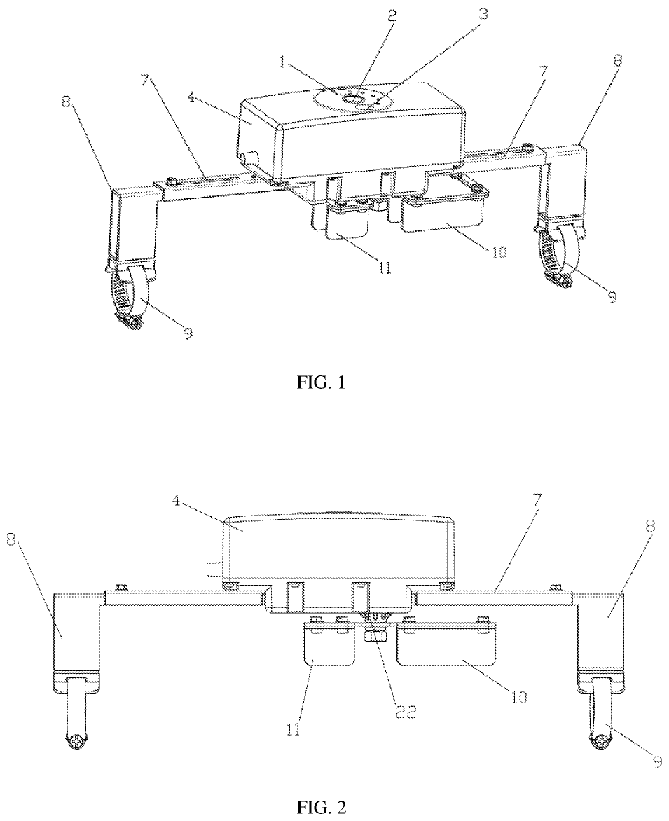

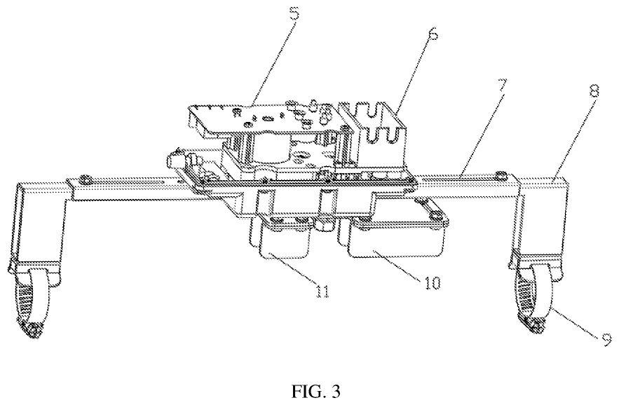

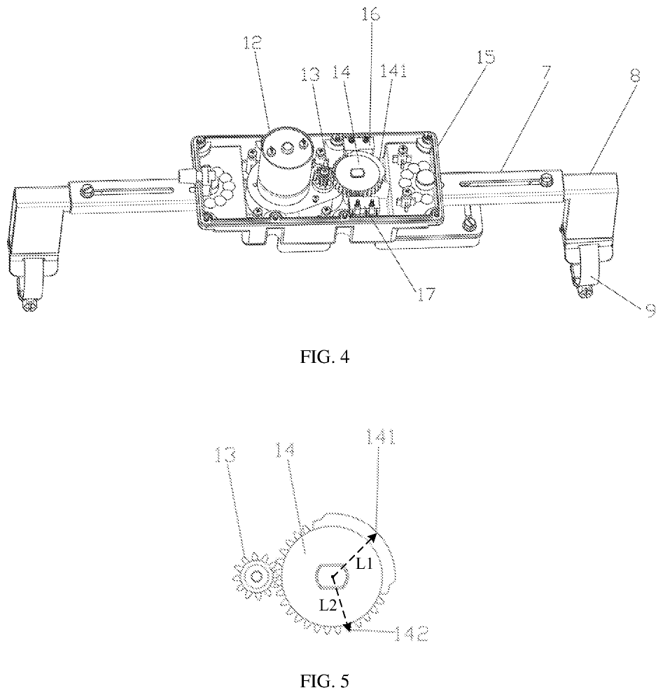

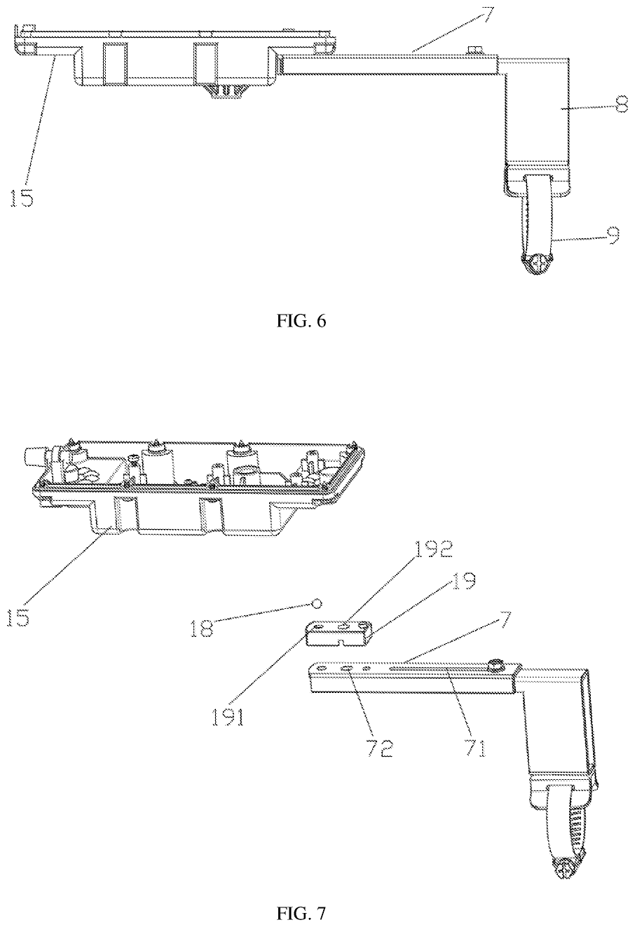

### DESCRIPTION OF NUMERICAL REFERENCES IN DRAWINGS

ON touch key 1, battery enable touch key 2, OFF touch key 3, upper casing 4, circuit board 5, battery case 6, movable slide bar 7, sliding groove 71, second positioning hole 72, movable stand 8, laryngeal hoop 9, first baffle 10, second baffle 11, motor assembly 12, motor gear 13, limit gear 14, cam part 141, gear teeth part 142, lower casing 15, first limit switch 16, second limit switch 17, steel ball 18, slide bar positioning buckle 19, recess 191, first positioning hole 192, steel ball receiving groove 20, turning arm 21, shaft 22.

### DETAILED DESCRIPTION OF EMBODIMENTS

The technical solutions in the embodiments of the invention will be clearly and completely described below, with reference to the accompanying drawings in the embodiments of the invention. Apparently, the described embodiments are merely some of the embodiments of the invention, not all embodiments. Based on the described embodiments of the invention, all other embodiments obtained by those skilled in the art without any creativity should belong to the protective scope of the invention.

It is noted that, in the embodiments of the invention, all directional indications (such as “upper”, “lower”, “left”, “right”, “front”, “rear”, etc.) are merely for indicating relative positional relationships and motions among various components under certain specific postures (as shown in the drawings), if the specific postures change, the directional indication will change accordingly.

In the description of the invention, unless otherwise clearly stated and limited, terms “connected”, “fixed” and so on should be understood broadly. For instance, “fixed” can be a fixed connection, a detachable connection or an integral connection; can be a mechanical connection, can also be an electrical connection; can be a direct connection, can also be an indirect connection by an intermediary, can be an internal communication of two elements or an interaction between two elements, unless otherwise clearly defined. A person skilled in the art can understand concrete meanings of the terms in the invention as per specific circumstances.

Moreover, terms such as “first” and “second” are merely for the purpose of illustration and cannot be understood as indicating or implying the relative importance or implicitly indicating the number of the technical feature. Therefore, features defined by “first” and “second” can explicitly or implicitly include one or more the features. In the description of the invention. In addition, the technical solutions of various embodiments may be combined together, any combination must be based on the realization of ordinary skilled person in the art. When a combination of technical solutions is contradictory or unable to be realized, it should be considered that such the combination of technical solutions does not exist and is not within the protection scope of the invention.

The invention provides a fluid valve control device exemplarily including: a housing, a motor assembly 12, a motor gear 13, a limit gear 14, movable slide bars 7, movable stands 8, laryngeal hoops 9, a turning arm 21 and baffles. The motor assembly 12, the motor gear 13 and the limit gear 14 are arranged in the housing. The movable slide bars 7, the movable stands 8 and the laryngeal hoops 9 each are two in number and together forms two sets respectively arranged two sides of the housing. The movable slide bars 7 are connected with a bottom of the housing. Each of the movable slide bars 7 is formed with a sliding groove 71, the movable stands 8 are respectively connected with the movable slide bars 7 and slidable along the sliding grooves 71 of the movable slide bars 7. The movable stands 8 are connected with the laryngeal hoops 9 respectively. The motor assembly 12 is configured (i.e., structured and arranged) for driving the motor gear 13 to rotate. The motor gear 13 is configured for driving the limit gear 14 to rotate. The limit gear 14 is configured for driving the turning arm 21 to rotate via a shaft 22. The baffles are fixedly connected with the turning arm 21.

In an illustrated embodiment, the housing includes an upper casing 4 and a lower casing 15.

In an illustrated embodiment, an upper surface of the upper casing 4 is disposed with an ON touch key 1, a battery enable touch key 2 and an OFF touch key 3.

In an illustrated embodiment, a slide bar positioning buckle 19 is further provided. The slide bar positioning buckle 19 is arranged between the lower casing 15 and the movable slide bar 7. A bottom of the lower casing 15 is formed with a plurality of steel ball receiving grooves 20, the slide bar positioning buckle 19 is formed with a recess 191 matched with any one of the plurality of steel ball receiving grooves 20, and a steel ball 18 is arranged between one of the steel ball receiving grooves 20 and the recess 191. The slide bar positioning buckle 19 is further formed with a first positioning hole 192, and one of the movable slide bars 7 is formed with a second positioning hole 72.

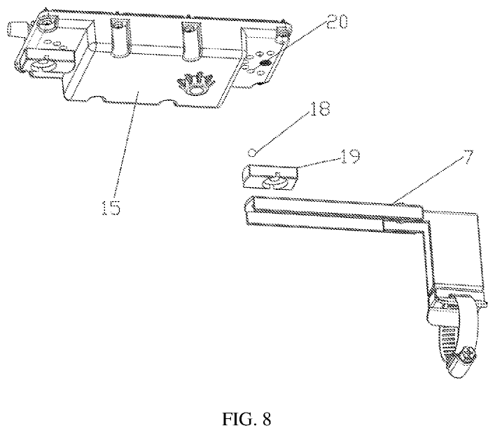

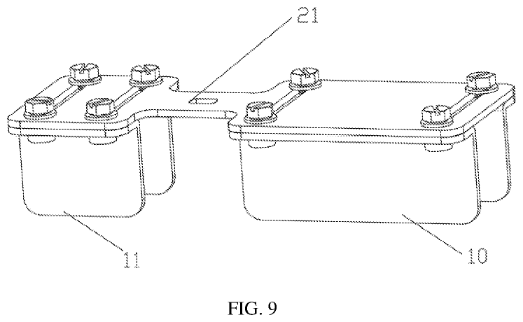

More specifically, as illustrated in FIG. 7 and FIG. 8, the steel ball receiving grooves 20 are arranged at the bottom of the lower casing 15 in an arc shape, so that the steel ball 18 can be installed in any one of the steel ball receiving grooves 20. For a pipe that is not straight, an angle of movable slide bar 7 can be adjusted by adjusting a position of the steel ball 18 in advance. By passing a screw through the second positioning hole 72 and the first positioning hole 192, the housing is relatively fixed with the movable slide bar 7.

In an illustrated embodiment, each the movable stand 8 is slidable along the sliding groove 71 of the movable slide bar 7, thereby adjusting a relative length of the movable stand 8 to adapt to pipes of different lengths.

In an illustrated embodiment, the baffles include first baffles 10 and second baffles 11. The first baffles 10 and the second baffles 11 are arranged at two sides of the shaft 22 of the limit gear 14 respectively.

In an illustrated embodiment, the first baffle 10 is a L-shaped baffle, the second baffle 11 is a L-shaped baffle. The first baffle 10 is a large-sized baffle, and the second baffle 11 is a small-sized baffle. By the arrangement of the large-sized baffles and the small-sized baffles, it can meet different types of fluid valve handles (e.g., water valve handles).

In an illustrated embodiment, the limit gear 14 includes a gear teeth part 142 and a cam part 141.

In an illustrated embodiment, a distance L1 between the cam part 141 and a circle center of the limit gear 14 is greater than a distance L2 between the gear teeth part 142 and the circle center of the limit gear 14.

In an illustrated embodiment, a central angle of the cam part 141 is in a range from 90 degrees to 100 degrees.

In an illustrated embodiment, a first limit switch 16 and a second limit switch 17 are further provided. The first switch 16 and the second limit switch 17 are disposed in the housing. The first limit switch 16 and the second limit switch 17 are arranged at two sides of the limit gear 14 respectively. During the limit gear 14 is rotating, the cam part 141 of the limit gear 14 can abut against the first limit switch 16 and the second limit switch 17, but the gear teeth part 142 of the limit gear 14 cannot abut against the first limit switch 16 and the second limit switch 17.

More specifically, a circuit board 5 is further provided. The first limit switch 16 and the second limit switch 17 are connected with the circuit board 5. When the cam part 141 of the limit gear 14 abuts against the first limit switch 16, a fluid valve (e.g., water valve) is in a maximum fluid discharge state, and when the cam part 141 of the limit gear 14 abuts against the second limit switch 17, the fluid valve is in a closed state.

In an illustrated embodiment, a battery case 6 is further provided. A backup DC power supply is placed in the battery case 6. When an external power supply is cut off, the backup DC power supply can be used as a temporary power supply for the fluid valve control device.

In an illustrated embodiment, a joint of the shaft 22 with the lower casing 15 is disposed with a waterproof ring and applied with a waterproof oil. A joint of the upper casing 4 with the lower casing 15 is disposed with a sealing silicone and applied with a waterproof oil.

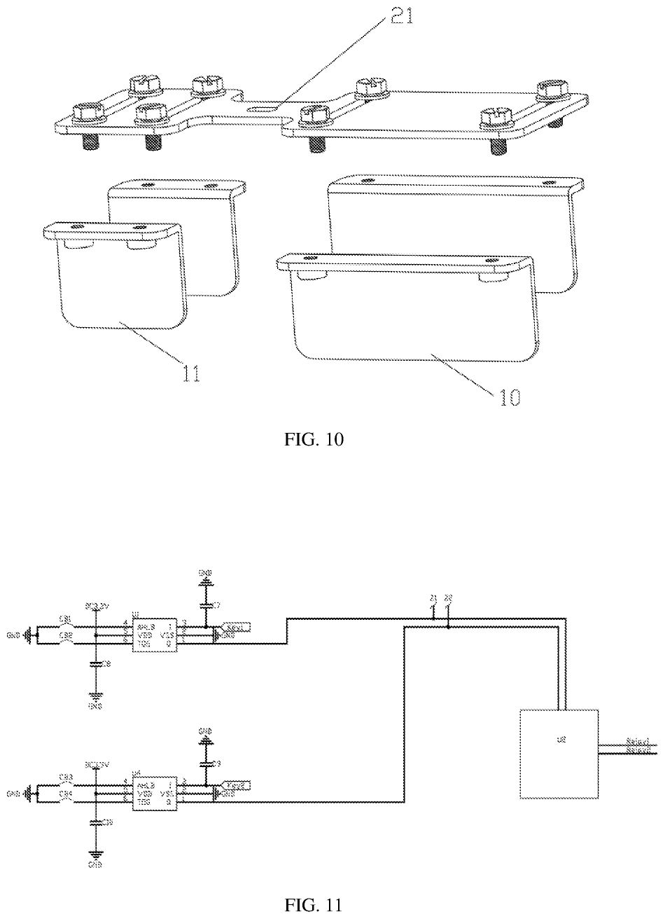

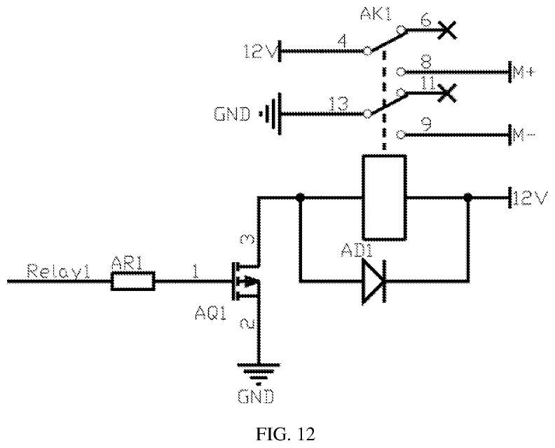

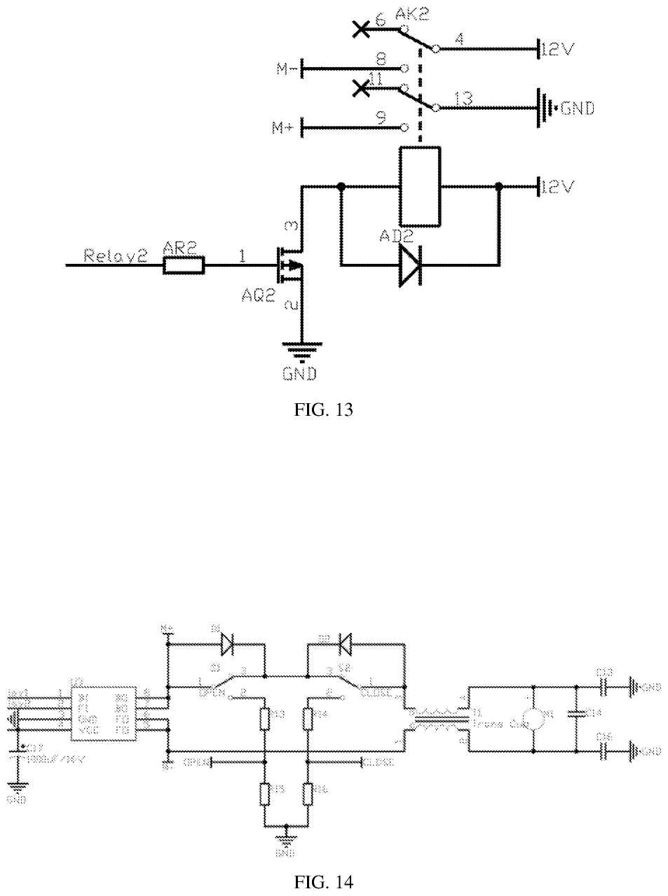

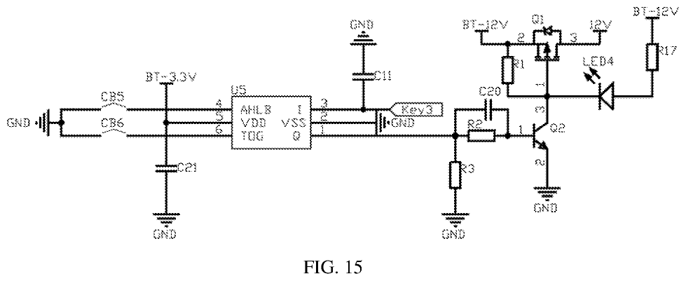

A motor control process of an embodiment of the invention will be described below with reference to FIG. 11 through FIG. 15.

When a finger touches the ON touch key 1 on the upper surface of the upper casing 4, a pin 1 of a first chip U1 outputs a low-level signal of 0V to a second chip U2, the second chip outputs a signal of Relay1, the Relay1 is a high-level of 3V applied to a transistor AQ1 to drive a contact point of a first relay AK1 to operate, the pin 4 and the pin 8 of the first relay AK1 are conducted, the pin 13 and the pin 9 of the first relay AK1 are conducted. As a result, a power supply of 12V passes from the pin 4 of the first relay AK1 to the terminal M+ through the pin 8, then passes through the pins 1-3 of the first limit switch 16 S1, the pins 3-1 of the second limit switch 17 S2 and the pins 3-4 of a first inductor T1 to enter into a positive electrode of a DC motor M1, after being outputted from a negative electrode of the DC motor M1, it passes the pins 2-1 and reaches the terminal M−, and finally is connected to GND through the pins 9-13 of the first relay AK1. At this time, the DC motor M1 rotates reversely, the motor gear 13 of the DC motor rotates anti-clockwise to bring the limit gear 14 to rotate clockwise, the turning arm 21 is driven to clockwise move by the shaft 22 on the limit gear 14, the water valve handle is driven to open the switch of a water pipe to discharge water.

When the finger leaves the ON touch key 1, the pin 1 of the first chip U1 outputs a high-level signal of 3V to the second chip U2, the second chip U2 outputs the signal of Relay1, and the signal of Relay1 is a low-level of 0V applied to the transistor AQ1 to cut off the first relay AK1, and the contact point of the first relay AK1 is reversed, the motor loses the power and stops rotating, the water valve handle will stop at an angle corresponding to a required water flow. When the cam part 141 rotates clockwise to a light contact point of the first limit switch 16 S1, the contact point is pressed, the contact points 1-3 of the first limit switch 16 S1 is turned off, the power supply is stopped, the motor is forced to be turned off, it means that the water valve switch is in the maximum flow discharge state.

When the finger touches the OFF touch key 3 on the surface of the upper casing 4, the pin 1 of a fourth chip U4 outputs a low-level signal of 0V to the second chip U2, the second chip U2 then outputs a signal of Relay2, the Relay2 is a high-level of 3V applied onto a transistor AQ2 to drive the contact point of a second relay AK2 to operate. The pins 4-8 of the second relay AK2 are conducted, the pins 13-9 of the second relay AK2 are conducted. The power supply of 12V passes from the pin 4 of the second relay AK2 to the terminal M− through the pin 8, then passes through the pins 1-2 of the first inductor T1 and enters into the negative electrode of the DC motor M1, after being outputted from the positive electrode of the DC motor M1, it passes the pins 4-3 of the first inductor T1, the pins 1-3 of the second limit switch 17 S2, the pins 3-1 of the first limit switch 16 S1 and reaches the terminal M+, and finally is connected to GND through the pins 9-13 of the second relay AK2. At this time, the DC motor M1 rotates forwardly, the motor gear 13 of the DC motor rotates clockwise to bring the limit gear 14 to rotate anti-clockwise, the turning arm 21 is driven to move anti-clockwise by the shaft 22 on the limit gear 14, the water valve handle is driven to decrease the water flowage of the water pipe. When the finger leaves the OFF touch key 3, the pin 1 of the fourth chip U4 outputs a high-level signal of 3V to the second chip U2, the second chip U2 outputs the signal of Relay2, the Relay2 is a low-level of 0V applied onto the transistor AQ2 to cut off the second relay AK2 resulting from loss of power, the contact point of the AK2 is reversed, the DC motor M1 stops rotating resulting from loss of power, the handle will stop at an angle corresponding to a required water flow. When the cam part 141 anti-clockwise rotates to a light contact point of the second limit switch 17 S2, the contact point is pressed, the contact points 1-3 of the second limit switch 17 S2 is turned off, the power supply is stopped, the motor is forced to be turned off, it means the water valve switch is in the closed state.

In an embodiment of the invention, a third chip U3 may be provided. When the third chip U3 is employed, the transistor AQ1, the first relay AK1, the transistor AQ2 and the second relay AK2 are replaced. Alternatively, when the transistor AQ1, the first relay AK1, the transistor AQ2 and the second relay AK2 are used, the third chip U3 is not used.

When the finger touches the middle battery enable touch key 2 on the surface of the upper casing 4, a pin 1 of a fifth chip U5 outputs a high-level signal of 3V to control transistors Q1 and Q2 to be turned on, a DC power BT-12V of the built-in battery passes from the pin 2 of the transistor Q1 to the pin 1 of the transistor Q1, so as to control the DC power BT-12V to be connected to a control system when the external power supply is cut off, ensuring that the fluid valve control device can continue to use.

When the finger touches the middle battery enable touch key 2 on the surface of the upper casing 4 again, the pin 1 of the fifth chip U5 outputs a low-level signal of 0V to the pin 1 of the transistor Q2, the transistor Q2 is turned off, the transistor Q1 is turned off correspondingly, the pins 2-1 of the transistor Q1 is not conducted, the DC power BT-12V of the built-in battery can not flow to the 12V of pin 3 of the transistor Q1, the power supply provided by the battery is turned off.

When a mobile phone remote network control is used, a corresponding wireless control host system receives on/off command from the mobile phone, the fluid valve control device receives a control command from the host system via an antenna on the circuit board 5 and sends it to the second chip U2, the second chip U2 judges the on/off signal value and outputs a corresponding control signal to the corresponding relay K1 or K2 (or U3), so as to drive the DC motor M1 to rotate forwardly or reversely and thereby drive the turning arm 21 of the fluid valve control device to rotate anti-clockwise or clockwise, the purpose of controlling opening or closing of the fluid valve handle and the angle control of fluid flow are achieved consequently.

The beneficial effects of the embodiments of the invention are as follows:

The fluid valve control device as provided by the invention uses two laryngeal hoops 9 respectively located on the left and right to connect with the fluid pipe, uses the baffles to connect with the fluid valve handle, uses the motor assembly 12 to drive the motor gear 13, and uses the motor gear 13 to drive the limit gear 14 to rotate. The limit gear 14 then drives the turning arm 21 to rotate by the shaft 22 and thereby brings the baffles to drive the fluid valve handle to rotate, so as to control the size of fluid flowage. In the invention, fixed points of the fluid valve control device with the fluid pipe are at two ends, which are tightened and fixed by the laryngeal hoops 9, so that the two fixed points of the fluid valve control device and the shaft are located in a same horizontal plane, the problem that the switch is not in place due to the dislocation and offset of the shaft and the fluid valve handle is solved. The movable slide bars 7 of the invention can be adjusted at different angles according to different fluid pipes, and the movable stands 8 can carry out length telescopic adjustments along the movable slide bars 7 and therefore a wide range of application scenarios is achieved. The invention further may make the fluid valve handle stay at any angle between 0 and 90 degrees and therefore can save water resources. Meanwhile, the invention also adopts a touch sensing method to control the fluid valve, and also has the wireless remote network control function. A remote network connection between a mobile phone APP and the host control system can be established, and then the host control system carries out the remote control. Therefore, the invention is particularly suitable for garden watering, agricultural irrigation and other production and living works as well as the control of gas pipeline switch. The remote control technology can reduce the expenditure cost of production labor and reduce the waste of water resources.

The above are only preferred embodiments of the invention, and does not limit the patent protection scope of the invention. On the premise of not departing from the spirit and scope of the invention, the invention will have various modification and improvements. Under the inventive concept of the invention, equivalent structural transformations made by using the description and the attached drawings of the invention, or direct/indirect application in other related technical fields are all included in the scope of patent protection of the invention.

What is claimed is:

1. A fluid valve control device comprising a housing, a motor assembly, a motor gear, a limit gear, movable slide bars, movable stands, laryngeal hoops, a turning arm and baffles;
wherein the motor assembly, the motor gear and the limit gear are arranged in the housing; the movable slide bars, the movable stands and the laryngeal hoops together form two sets respectively arranged two sides of the housing, the movable slide bars are connected with a bottom of the housing, the movable slide bars are formed with sliding grooves respectively, the movable stands are connected with the movable slide bars respectively and slidable along the sliding grooves of the movable slide bars respectively, and the movable stands are connected with the laryngeal hoops respectively;
wherein the motor assembly is configured for driving the motor gear to rotate, the motor gear is configured for driving the limit gear to rotate, the limit gear is configured for driving the turning arm to rotate via a shaft, and the baffles are fixedly connected with the turning arm.

2. The fluid valve control device as claimed in claim 1, further comprising a slide bar positioning buckle; wherein the slide bar positioning buckle is arranged between the housing and one of the movable slide bars, the bottom of the housing is disposed with a plurality of steel ball receiving grooves, the slide bar positioning buckle is disposed with a recess matched with any of the plurality of steel ball receiving grooves, and a steel ball is arranged between one of the plurality of steel ball receiving grooves and the recess; the slide bar positioning buckle is further disposed with a first positioning hole, and one of the movable slide bars is disposed with a second positioning hole.

3. the fluid valve control device as claimed in claim 1, wherein the baffles comprise first baffles and second baffles; the first baffles and the second baffles are arranged at two sides of the shaft of the limit gear respectively.

4. The fluid valve control device as claimed in claim 3, wherein each of the first baffles is a L-shaped baffle, and each of the second baffles is a L-shaped baffle.

5. The fluid valve control device as claimed in claim 1, wherein the limit gear comprises a gear teeth part and a cam part.

6. The fluid valve control device as claimed in claim 5, wherein a distance between the cam part and a circle center of the limit gear is greater than a distance between the gear teeth part and the circle center of the limit gear.

7. The fluid valve control device as claimed in claim 5, wherein a central angle of the cam part is in a range from 90 degrees to 100 degrees.

8. the fluid valve control device as claimed in claim 5, further comprising a first limit switch and a second limit switch; wherein the first limit switch and the second limit switch are arranged in the housing, the first limit switch and the second limit switch are arranged at two sides of the limit gear respectively; during the limit gear rotates, the cam part of the limit gear is capable of abutting against the first limit switch and the second limit switch, but the gear teeth part of the limit gear is not capable of abutting against the first limit switch and the second limit switch.

9. The fluid valve control device as claimed in claim 8, further comprising a circuit board; wherein the first limit switch and the second limit switch are connected with the circuit board, a fluid valve is in a maximum fluid discharging state when the cam part of the limit gear abuts against the first limit switch, and the fluid valve is in a closed state when the cam part of the limit gear abuts against the second limit switch.

10. The fluid valve control device as claimed in claim 1, wherein the housing comprises an upper casing and a lower casing.
